(19) United States
(12) Patent Application Publication
(10) Pub. No.: US 2008/0160717 A1
(43) Pub. Date: Jul. 3, 2008

(54) Method of Forming Trench in Semiconductor Device

(76) Inventor: Cheon Man Shim, Yeongdeungpo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/929,966

(22) Filed: Oct. 30, 2007

(30) Foreign Application Priority Data
Dec. 27, 2006 (KR) 10-2006-0135570

(51) Int. Cl. H01L 21/762

(52) U.S. Cl. 438/425; 257/E21.546

(57) ABSTRACT

Provided is a method of forming a trench in a semiconductor device capable of improving gap-fill performance. In one method of forming a trench in a semiconductor device, an oxide layer and a mask layer are sequentially formed on a substrate. The mask layer is selectively patterned to form a mask layer pattern. The oxide layer and the substrate are patterned using the mask layer pattern as a mask to form an oxide layer pattern and a trench having a predetermined depth from a surface of the substrate. A liner oxide layer is formed in the trench. A wet etching process is performed on the substrate to remove the liner oxide layer from the trench. A device isolation layer is formed in the trench from which the liner oxide layer has been removed. Then, the mask layer pattern and the oxide layer pattern are removed from the substrate.

### CROSS-REFERENCE TO RELATED APPLICATION

The present application claims the benefit under 35 U.S.C. §119 of Korean Patent Application No. 10-2006-0135570, filed Dec. 27, 2006, which is hereby incorporated by reference in its entirety.

### BACKGROUND

As manufacturing technology of a semiconductor device develops, and its applications expand, research is actively conducted to increase the degree of integration of the semiconductor device. With the increase in the integration degree of the semiconductor device researches are actively ongoing to be able to achieve a fine structure. A technology for reducing a device isolation layer that separates devices is drawing attention as one area that can contribute to the high integration degree of a device.

A related-art device isolation technology may include a local oxidation of silicon (LOCOS) technology in which a thick oxide layer is selectively grown on a semiconductor substrate to form a device isolation layer. However, in the LOCOS technology, because the oxide layer is formed even to a portion at which side diffusion of the device isolation layer is not desired, the reduction of the width of the device isolation layer is limited. Accordingly, it is very difficult to apply the LOCOS technology to a semiconductor device having a device design dimension reduced down to the submicron level or lower.

In order to overcome such a limitation of the LOCOS technology, shallow trench isolation (STI) technology has emerged, in which a shallow trench is formed in a semiconductor substrate through an etching process, and an insulating material fills the shallow trench, thereby allowing a device isolation region to be reduced compared to the LOCOS technology.

In the related-art STI technology, a liner insulating layer is formed thinly on a side surface of a trench for the device isolation.

The liner insulating layer that has a predetermined thickness causes the width of the trench to be reduced. Such a reduction in the width of the trench causes serious problems in view of the recent trend toward reducing width the device isolation layer.

In detail, the liner insulating layer makes the width of the trench smaller than a designed value. When the device isolation layer fills the trench having the smaller width than the designed value, defects such as a void may occur in the device isolation layer because of the width of the trench that is relatively narrow with respect to the height thereof. This is because the reduced width of the trench increases the aspect ratio.

Also, the device isolation layer may be excessively deposited at a corner of the trench at the time of gap-fill of the device isolation layer, thereby causing an overhang. The overhang acts as a main cause of a void, which causes gap-fill defects.

The void in the device isolation layer deteriorates not only a mechanical strength of the device but also an electrical insulating property.

### BRIEF SUMMARY

Embodiments of the present invention provide a method of forming a trench of a semiconductor device capable of improving gap-fill performance. According to an embodiment, gap-fill defects caused by an overhang can be inhibited by securing a process margin of a trench.

In an embodiment, a method of forming a trench in a semiconductor device includes: sequentially forming an oxide layer and a mask layer on a substrate; selectively patterning the mask layer to form a mask layer pattern; patterning the oxide layer and the substrate using the mask layer pattern as a mask to form an oxide layer pattern and a trench, the trench having a predetermined depth from a surface of the substrate; forming a liner oxide layer in the trench; performing a wet etching process on the substrate to remove the liner oxide layer from the trench; forming a device isolation layer in the trench from which the liner oxide layer has been removed; and removing the mask layer pattern and the oxide layer pattern from the substrate. In one embodiment, the mask layer is a nitride layer.

The details of one or more embodiments are set forth in the accompanying drawings and the description below. Other features will be apparent from the description, drawings, and the appended claims.

### BRIEF DESCRIPTION OF THE DRAWINGS

FIGS. 1A to 1H are cross-sectional views for describing a process of forming a trench of a semiconductor device according to an embodiment of the present invention.

### DETAILED DESCRIPTION

Embodiments of a method of forming a trench for isolation are provided, capable of an improved gap-fill performance.

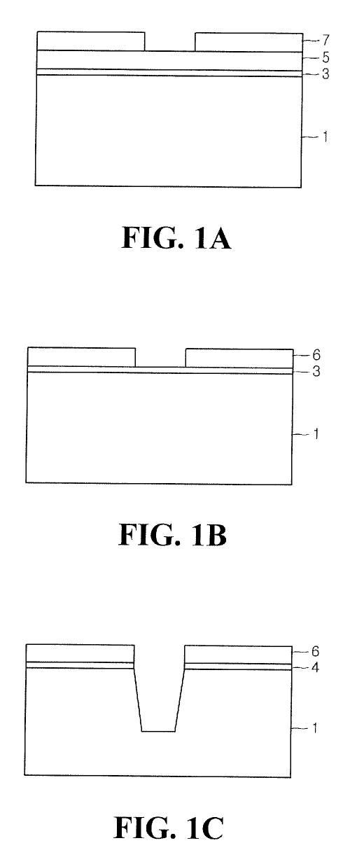

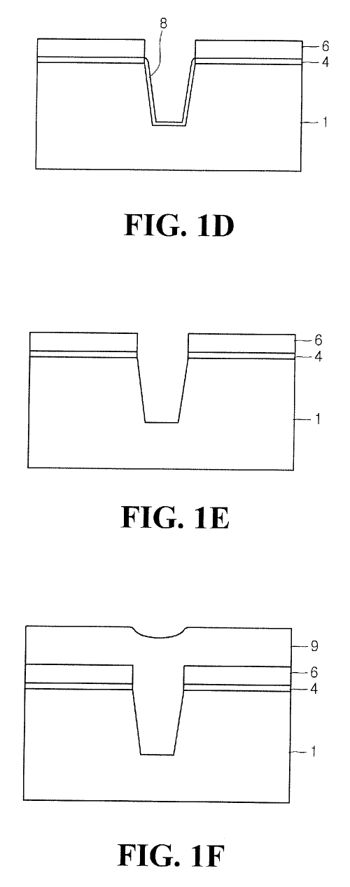

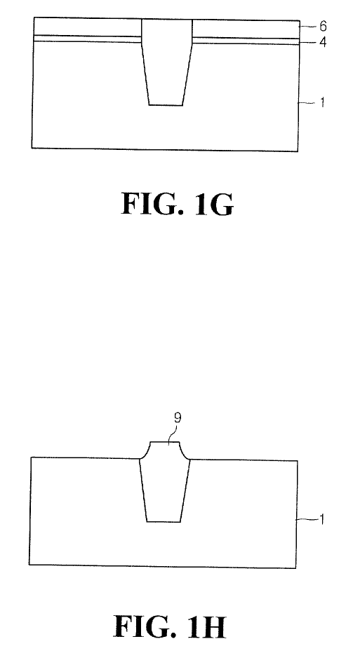

Referring to FIG. 1A, an oxide layer 3 and a mask layer 5 can be sequentially stacked on a semiconductor substrate 1. The semiconductor substrate 1 can include silicon (Si). The mask layer 5 can be an insulating layer. In a preferred embodiment, the insulating layer 5 is a nitride layer, but embodiments are not limited thereto. Photoresist can be formed on the insulating layer 5, and then exposed and developed, to form a photoresist pattern 7 exposing the insulating layer 5 at a region for forming a trench.

As illustrated in FIG. 1B, the insulating layer 5 can be etched using the photoresist pattern 7 as a mask until the oxide layer 3 is exposed to form an insulating layer pattern 6. Thus, the insulating layer 5 on the trench forming region is removed.

Thereafter, the photoresist pattern 7 is stripped away. Accordingly, the oxide layer 3 is covered with the insulating layer pattern 6 except at the trench forming region.

Referring to FIG. 1C, the oxide layer 3 and the semiconductor substrate 1 can be selectively etched using the insulating layer pattern 6 as a mask to form an oxide layer pattern 4 and a trench having a predetermined depth from a surface of the semiconductor substrate 1. The trench may be formed through a dry etching process such as reactive ion etching (RIE). The insulating layer material is selected to have a different etching selectively from both the oxide layer and the semiconductor substrate. In the dry etching process, ions are accelerated by energy so as to physically or arbitrarily bombard with the semiconductor substrate 1, thereby removing silicon atoms of the semiconductor substrate 1. When the silicon atoms are removed physically or arbitrarily from the semiconductor substrate 1, the surface of the trench becomes highly unstable. In order to stabilize the unstable state of the trench, a liner oxide layer (not shown) is formed.

Referring to FIG. 1D, a thermal oxidation process can be performed on the semiconductor substrate 1 to thermally oxidize the surface of the trench, thereby forming a liner oxide layer 8. The liner oxide layer 8 may have a thickness ranging from 50 to 150 Å. The liner oxide layer 8 can be generated from a surface of the semiconductor substrate 1 exposed to the outside. Since an upper surface of the semiconductor substrate 1 is covered with the insulating layer pattern 6 and thus is not exposed to the outside, the liner oxide layer 8 cannot be formed on the upper surface of the semiconductor substrate 1. However, a portion of the semiconductor substrate 1 corresponding to side surfaces and a bottom surface of the trench is exposed to the outside, so that silicon of the side surfaces and the bottom surface of the trench reacts with oxygen, thereby forming the liner oxide layer 8.

When the inside of the semiconductor substrate 1 is patterned to form a trench, a silicon lattice of the surface of the trench becomes unstable because of stress. The unstable state of the surface of the trench may accelerate deterioration of insulating performance and generation of a leakage current in operation of a device, which are caused by dislocation between a device isolation layer (not shown) and the surface of the trench.

For this reason, the liner oxide layer 8 is formed on the surface of the trench, so that the surface of the trench can be recovered to a stable state.

Referring to FIG. 1E, the liner oxide layer 8 is removed using an etching process. The etching process may be a wet etching process. An etching solution used in the wet etching process may be an organic solution or an inorganic solution. For example, NE14 solution may be used as the organic solution, but the organic solution used in embodiments of the present invention is not limited thereto. Likewise, diluted hydrofluoric acid HF (DHF) or buffered HF (BHF) may be used as the inorganic solution, but the inorganic solution used in embodiments of the present invention is not limited thereto.

Conditions of a wet-etching process using BHF as an etching solution according to an embodiment will now be described below.

In particular, a mixture ratio of NH₄F to HF may range from 30:1 to 30:15. The process time may range from 5 to 200 seconds. A rotation speed of the semiconductor substrate 1 may range from 600 to 1000 RPM. The flow rate may range from 20 to 60 kPa. The temperature may range from 10 to 100° C.

Conditions of a wet etching process using DHF as an etching solution according to an embodiment will now be described below.

In particular, a mixture ratio of deionized water (DIW) to HF ranges from 100:1 to 1000:1. The process time may range from 10 to 2000 seconds. A rotation speed of the semiconductor substrate 1 may range from 600 to 1000 RPM. The flow rate may range from 20 to 60 kPa. The temperature may range from 10 to 100° C.

When the semiconductor substrate 1 is dipped into an etching solution including BHF or DHF, the insulating layer pattern 6 of the semiconductor substrate 1 does not react with the etching solution and remains as it is, but the liner oxide layer 8 of the semiconductor substrate 1 easily reacts with the etching solution, and therefore is etched and entirely removed.

When the wet etching process is performed under the rough conditions as set above, the liner oxide layer 8 may be almost completely removed.

In other words, the wet etching process may be continuously performed until the surface of the semiconductor substrate 1 contacting the liner oxide layer 8 is exposed.

The surface of the trench in the unstable state may be maintained in a stable state by the liner oxide layer 8. After the liner oxide layer 8 is removed, the surface of the trench exposes the silicon of the semiconductor substrate 1 again. However, since the liner oxide layer 8 is removed by a wet etching process, the silicon may be continuously maintained in the stable state. That is, the wet etching process is not a physical or arbitrary etching process, but is an etching process using a chemical reaction for the removal. Thus, only the liner oxide layer 8 reacting with the corresponding etching solution is removed through the chemical reaction, so that the arrangement state of the exposed silicon can be stabilized.

In an embodiment, since the liner oxide layer 8 is removed, the width of the trench can be substantially expanded, so that gap-fill performance of a device isolation layer (not shown) can be improved.

Referring to FIG. 1F, a device isolation layer 9 can be deposited on the semiconductor substrate 1 from which the liner oxide layer 8 has been removed.

If the trench has a relatively wide width, the device isolation layer 9 may be formed through one deposition process.

However, if the trench has a relatively narrow width and the device isolation layer 9 is formed through one deposition process, the device isolation layer 9 may be formed relatively thickly at upper corners of the trench. The thick portion of the device isolation layer 9 located at the upper corners of the trench makes it difficult to form the device isolation layer 9 at side surfaces under the corners of the trench. Thus, a defect such as a void may be caused inside the deposited device isolation layer 9.

Therefore, when the width of the trench is narrow, at least two deposition processes may be repetitively performed. As the need arises, an etching process may also be added between the deposition processes so that the thick portion of the device isolation layer can be made to be thin at the upper corners of the trench.

Also, a considerable height difference exists between the bottom surface of the trench and a top surface of the insulating layer pattern 6. Therefore, the device isolation layer 9 may be formed to have an enough thickness to fill the entire trench.

According to embodiments of the present invention, the liner oxide layer 8 is removed, and the width of the trench is substantially expanded, thereby increasing a gap-fill margin. Accordingly, the device isolation layer 9 can be formed in the trench without a void. That is, since the liner oxide layer 8 is removed, and the width of the trench is widened, a possibility of void generation can be reduced as compared to the related art, and the gap-fill performance of the device isolation layer 9 can be remarkably improved.

Referring to FIG. 1G, the device isolation layer 9 can be polished using a chemical mechanical polishing (CMP) process until the insulating layer pattern 6 is exposed, thereby providing the device isolation layer 9 in the trench.

Referring to FIG. 1H, the insulating layer pattern 6 can be removed by a wet etching process using an etching solution including a phosphoric acid. Thereafter, the oxide layer pattern 4 may be removed by a washing process or a wet etching process.

The upper corners of the device isolation layer 9 formed in the trench may be partially removed when the insulating layer pattern 6 and the oxide layer pattern 4 are removed, so that the upper corners may have a round shape.

As described above, according to an embodiment, the liner oxide layer is removed to secure a process margin of the trench. Accordingly, a gap-fill defect which may be caused by an overhang can be prevented.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although illustrative embodiments have been described herein, it should be understood that numerous other modifications and alternative embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of forming a trench in a semiconductor device, comprising:
sequentially forming an oxide layer and a mask layer on a substrate;
selectively patterning the mask layer to form a mask layer pattern;
patterning the oxide layer and the substrate using the mask layer pattern as a mask to form an oxide layer pattern and a trench, the trench having a predetermined depth from a surface of the substrate;
forming a liner oxide layer in the trench;
performing a wet etching process on the substrate to remove the liner oxide layer from the trench;
forming a device isolation layer in the trench from which the liner oxide layer has been removed; and
removing the mask layer pattern and the oxide layer pattern from the substrate.

2. The method according to claim 1, wherein forming the liner oxide layer comprises performing a thermal oxidation process.

3. The method according to claim 1, wherein performing the wet etching process comprises using an organic solution.

4. The method according to claim 3, wherein the organic solution is NE14 solution.

5. The method according to claim 1, wherein performing the wet etching process comprises using an inorganic solution.

6. The method according to claim 5, wherein the inorganic solution is buffered HF or diluted HF.

7. The method according to claim 6, wherein the inorganic solution is buffered HF; and wherein performing the wet etching process comprises using a mixture ratio of NH₄F and HF ranging from 30:1 to 30:15, a process time ranging from 5 to 200 seconds, a rotation speed of 600 to 1000 RPM, a flow rate ranging from 20 to 60 kPa, and a temperature ranging from 10 to 100° C.

8. The method according to claim 6, wherein the inorganic solution is diluted HF; and wherein performing the wet etching process comprises using a mixture ratio of deionized water to HF ranging from 100:1 to 1000:1, a process time ranging from 10 to 2000 seconds, a rotation speed ranging from 600 to 1000 RPM, a flow rate ranging from 20 to 60 kPa, and a temperature ranging from 10 to 100° C.

9. The method according to claim 1, wherein forming the device isolation layer comprises performing at least two deposition processes.

10. The method according to claim 9, further comprising performing an isolation layer etching process between each deposition process.

11. The method according to claim 1, wherein the wet etching process is performed until a surface of the substrate contacting the liner oxide layer is exposed.

12. The method according to claim 1, wherein the mask layer comprises a nitride layer.

13. The method according to claim 1, wherein the mask layer comprises an insulating layer having a different etching selectively than both the oxide layer and the substrate.
